(19) United States
(12) Patent Application Publication
(10) Pub. No.: US 2017/0207766 A1
(43) Pub. Date: Jul. 20, 2017

(54) CAP STRUCTURE FOR WAFER LEVEL PACKAGE

(71) Applicant: Qorvo US, Inc., Greensboro, NC (US)

(72) Inventors: Paul Stokes, Orlando, FL (US); Vishwavasu Potdar, Plano, TX (US)

(21) Appl. No.: 15/374,635

(22) Filed: Dec. 9, 2016

Related U.S. Application Data
(60) Provisional application No. 62/280,747, filed on Jan. 20, 2016.

(51) Int. Cl. H03H 9/10; H03H 9/02; H03H 9/13; H03H 9/17

(52) U.S. Cl. CPC H03H 9/105; H03H 9/17; H03H 9/02157; H03H 9/131; H03H 9/175

(57) ABSTRACT

A wafer level package (WLP) device includes a wafer level core and a cap structure. At least one component is formed in or on the wafer level core, and the cap structure resides on the top surface of the wafer level core and forms a cavity over the component. The cap structure includes a perimeter wall that rests on the top surface of the wafer level core and extends about the component. The perimeter wall has a top surface divided into a covered portion that extends along an inner portion and an uncovered portion that extends along an outer portion. The lid has a bottom surface, wherein an outer periphery of the bottom surface of the lid rests on and only covers the covered portion of the top surface of the perimeter wall.

### RELATED APPLICATIONS

This application claims the benefit of provisional patent application Ser. No. 62/280,747, filed Jan. 20, 2016, the disclosure of which is hereby incorporated herein by reference in its entirety.

### FIELD OF THE DISCLOSURE

The present disclosure relates to a cap structure for wafer level package.

### BACKGROUND

Acoustic resonators, such as Surface Acoustic Wave (SAW) and Bulk Acoustic Wave (BAW) resonators, are used in many high-frequency communication applications. BAW resonators are often employed in filter networks that operate at frequencies above 1.5 GHz and require a flat passband; have exceptionally steep filter skirts and squared shoulders at the upper and lower ends of the passband; and provide excellent rejection outside of the passband. SAW resonators are often employed at frequencies below 1.5 GHz. SAW- and BAW-based filters have relatively low insertion loss, tend to decrease in size as the frequency of operation increases, and are relatively stable over wide temperature ranges. As such, SAW- and BAW-based filters are the filters of choice for many 3rd Generation (3G) and 4th Generation (4G) wireless devices, and are destined to dominate filter applications for 5th Generation (5G) wireless devices. Most of these wireless devices support cellular, wireless fidelity (Wi-Fi), Bluetooth, and/or near field communications on the same wireless device, and as such, pose extremely challenging filtering demands. While these demands keep raising the complexity of the wireless devices, there is a constant need to improve the performance of SAW and BAW resonators and filters as well as decrease the cost and size associated therewith.

While performance, cost, and size are a driving developmental force, long-term reliability of these devices is critical. The acoustic resonators are typically fabricated with a cap structure that provides an air cavity about the active portion of the acoustic resonator. The cavity allows the active portion to resonate in free space. However, if an appropriate seal is not provided to separate the cavity from ambient, over-mold materials, moisture, dust, and other hazards may enter the cavity and adversely affect the functionality of the acoustic resonator. As such, there is a need for a cost-effective, easy to fabricate, and reliable cap structure for such devices.

### SUMMARY

The present disclosure relates to a wafer level package (WLP) device that includes a wafer level core and a cap structure. At least one component is formed in or on the wafer level core, and the cap structure resides on the top surface of the wafer level core and forms a cavity over the component. The cap structure includes a perimeter wall that rests on the top surface of the wafer level core and extends about the component. The perimeter wall has a top surface divided into a covered portion that extends along an inner portion and an uncovered portion that extends along an outer portion. The lid has a bottom surface, wherein an outer periphery of the bottom surface of the lid rests on and only covers the covered portion of the perimeter wall, such that the cavity is defined at least in part by portions of the bottom surface of the lid, an interior sidewall of the perimeter wall, and a top surface of the wafer level core.

In one embodiment, perimeter wall extends completely around the component. The cap structure may include interior walls that extend between the bottom surface of the lid and the top surface of the wafer level core. The interior walls separate different cavities that are defined within the cap structure.

In one embodiment, the covered portion of the top surface of the perimeter wall is no more than a maximum width. The maximum width may be defined as 0.002267*(WW)2+0.5539*WW−1.045, wherein WW is the overall width of the perimeter wall. This maximum width is particularly beneficial when the overall width of the perimeter wall is 5 μm to 50 μm, and a thickness of the lid is 10 μm to 100 μm. In other embodiments, the covered portion of the top surface of the perimeter wall is no more than 50%, 60%, 70%, or 80% of the overall width of the perimeter wall.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a conventional Bulk Acoustic Wave (BAW) resonator.

FIG. 2 is a graph of the magnitude and phase of impedance over frequency responses as a function of frequency for an ideal BAW resonator.

FIGS. 3A-3C are graphs of phase responses for various BAW resonator configurations.

FIG. 4 illustrates a conventional Bulk Acoustic Wave (BAW) resonator with a border ring.

FIG. 5 illustrates a conventional wafer level package (WLP) device including a cap structure, which is prone to delaminate from a WLP core of the WLP device.

FIG. 6 illustrates the cap structure of the WLP device of FIG. 5 delaminating from the top surface of the WLP core.

FIG. 7 illustrates a WLP device including a cap structure according to a first embodiment.

FIG. 8 is a top view of the cap structure of FIG. 7.

FIG. 9 illustrates a WLP device including a cap structure according to a second embodiment, wherein the cap structure provides multiple cavities.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The present disclosure relates to a wafer level package (WLP) device that includes a wafer level core and a cap structure. At least one component is formed in or on the wafer level core, and the cap structure resides on the top surface of the wafer level core and forms a cavity over the component. The cap structure includes a perimeter wall that rests on the top surface of the wafer level core and extends about the component. The perimeter wall has a top surface divided into a covered portion that extends along an inner portion and an uncovered portion that extends along an outer portion. The lid has a bottom surface, wherein an outer periphery of the bottom surface of the lid rests on and only covers the covered portion of the perimeter wall, such that the cavity is defined at least in part by portions of the bottom surface of the lid, an interior sidewall of the perimeter wall, and a top surface of the wafer level core.

Prior to delving into the details of the inventive concepts associated with this disclosure, overviews of a typical BAW resonator and wafer level package (WLP) device that includes a BAW resonator are provided. Notably, the typical WLP device includes a more conventional cap structure. The walls of this conventional cap structure are prone to delaminating from an underlying WLP core, as described below. While the BAW resonator is used in the examples for this disclosure, those skilled in art will recognize that other types of acoustic resonators, such as SAW resonators, and electronic components in general may be fabricated on the WLP device.

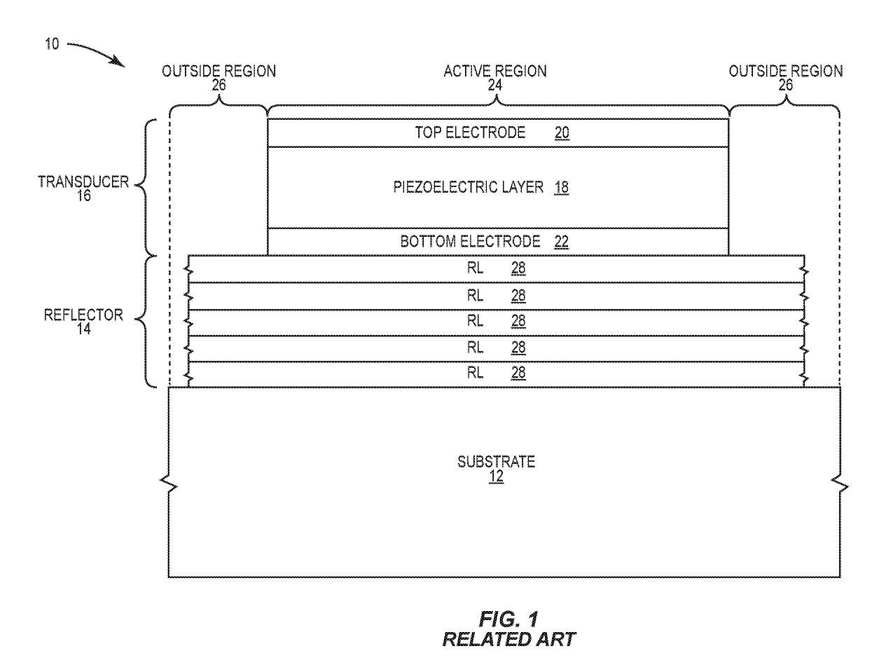

Bulk Acoustic Wave (BAW) resonators are used in many high-frequency filter applications. An exemplary BAW resonator 10 is illustrated in FIG. 1. The BAW resonator 10 generally includes a substrate 12, a reflector 14 mounted over the substrate 12, and a transducer 16 mounted over the reflector 14. The transducer 16 rests on the reflector 14 and includes a piezoelectric layer 18, which is sandwiched between a top electrode 20 and a bottom electrode 22. The top and bottom electrodes 20 and 22 may be formed of Tungsten (W), Molybdenum (Mo), Platinum (Pt), or like material, and the piezoelectric layer 18 may be formed of Aluminum Nitride (AlN), Zinc Oxide (ZnO) or other appropriate piezoelectric material. Although shown in FIG. 1 as each including a single layer, the piezoelectric layer 18, the top electrode 20, and/or the bottom electrode 22 may include multiple layers of the same material, multiple layers in which at least two layers are different materials, or multiple layers in which each layer is a different material.

The BAW resonator 10 is divided into an active region 24 and an outside region 26. The active region 24 generally corresponds to the section of the BAW resonator 10 where the top and bottom electrodes 20 and 22 overlap, and also includes the layers below the overlapping top and bottom electrodes 20 and 22. The outside region 26 corresponds to the section of the BAW resonator 10 that surrounds the active region 24.

For the BAW resonator 10, applying electrical signals across the top electrode 20 and the bottom electrode 22 excites acoustic waves in the piezoelectric layer 18. These acoustic waves primarily propagate vertically. A primary goal in BAW resonator design is to confine these vertically-propagating acoustic waves in the transducer 16. Acoustic waves traveling upwardly are reflected back into the transducer 16 by the air-metal boundary at the top surface of the top electrode 20. Acoustic waves traveling downwardly are reflected back into the transducer 16 by the reflector 14, or by an air cavity, which is provided just below the transducer in a Film BAW Resonator (FBAR).

The reflector 14 is typically formed by a stack of reflector layers (RL) 28, which alternate in material composition to produce a significant reflection coefficient at the junction of adjacent reflector layers 28. Typically, the reflector layers 28 alternate between materials having high and low acoustic impedances, such as tungsten (W) and silicon dioxide (SiO₂). While only five reflector layers 28 are illustrated in FIG. 1, the number of reflector layers 28 and the structure of the reflector 14 will vary from one design to another.

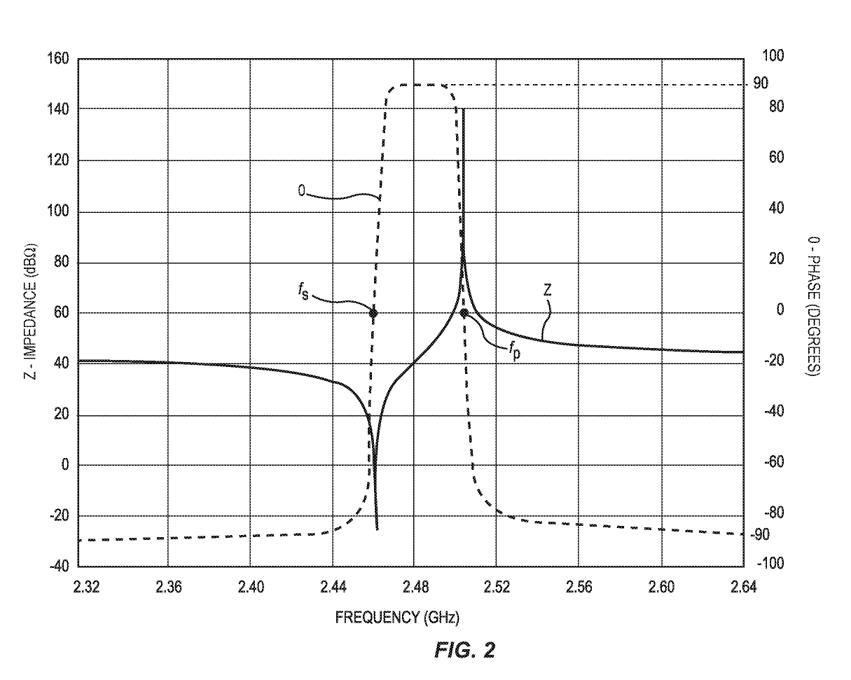

The magnitude (Z) and phase (φ) of the electrical impedance as a function of the frequency for a relatively ideal BAW resonator 10 is provided in FIG. 2. The magnitude (Z) of the electrical impedance is illustrated by the solid line, while the phase (φ) of the electrical impedance is illustrated by the dashed line. A unique feature of the BAW resonator 10 is that it has both a resonance frequency and an anti-resonance frequency. The resonance frequency is typically referred to as the series resonance frequency (fₛ), the anti-resonance frequency is typically referred to as the parallel resonance frequency (fₚ). The series resonance frequency (fₛ) occurs when the magnitude of the impedance, or reactance, of the BAW resonator 10 approaches zero. The parallel resonance frequency (fₚ) occurs when the magnitude of the impedance, or reactance, of the BAW resonator 10 peaks at a significantly high level. In general, the series resonance frequency (fₛ) is a function of the thickness of the piezoelectric layer 18 and the mass of the bottom and top electrodes 20 and 22.

For the phase, the BAW resonator 10 acts like an inductance that provides a 90° phase shift between the series resonance frequency (fₛ) and the parallel resonance frequency (fₚ). In contrast, the BAW resonator 10 acts like a capacitance that provides a −90° phase shift below the series resonance frequency (fₛ) and above the parallel resonance frequency (fₚ). The BAW resonator 10 presents a very low, near zero, resistance at the series resonance frequency (fₛ), and a very high resistance at the parallel resonance frequency (fₚ). The electrical nature of the BAW resonator 10 lends itself to the realization of a very high Q (quality factor) inductance over a relatively short range of frequencies, which has proven to be very beneficial in high frequency filter networks, especially those operating at frequencies around 1.8 GHz and above.

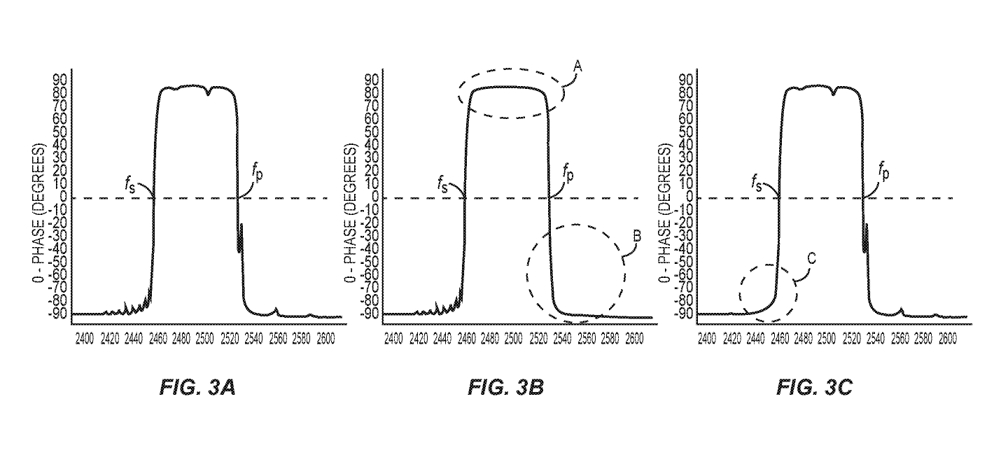

Unfortunately, the phase (φ) curve of FIG. 2 is representative of an ideal phase curve. In reality, approaching this ideal is challenging. A typical phase curve for the BAW resonator 10 of FIG. 1 is illustrated in FIG. 3A. Instead of being a smooth curve, the phase curve of FIG. 3A includes ripple below the series resonance frequency (fₛ), between the series resonance frequency (fₛ) and the parallel resonance frequency (fₚ), and above the parallel resonance frequency (fₚ). The ripple is the result of spurious modes, which are caused by spurious resonances that occur in corresponding frequencies. While the vast majority of the acoustic waves in the BAW resonator 10 propagate vertically, various boundary conditions about the transducer 16 result in the propagation of lateral (horizontal) acoustic waves, which are referred to as lateral standing waves. The presence of these lateral standing waves reduces the potential Q associated with the BAW resonator 10.

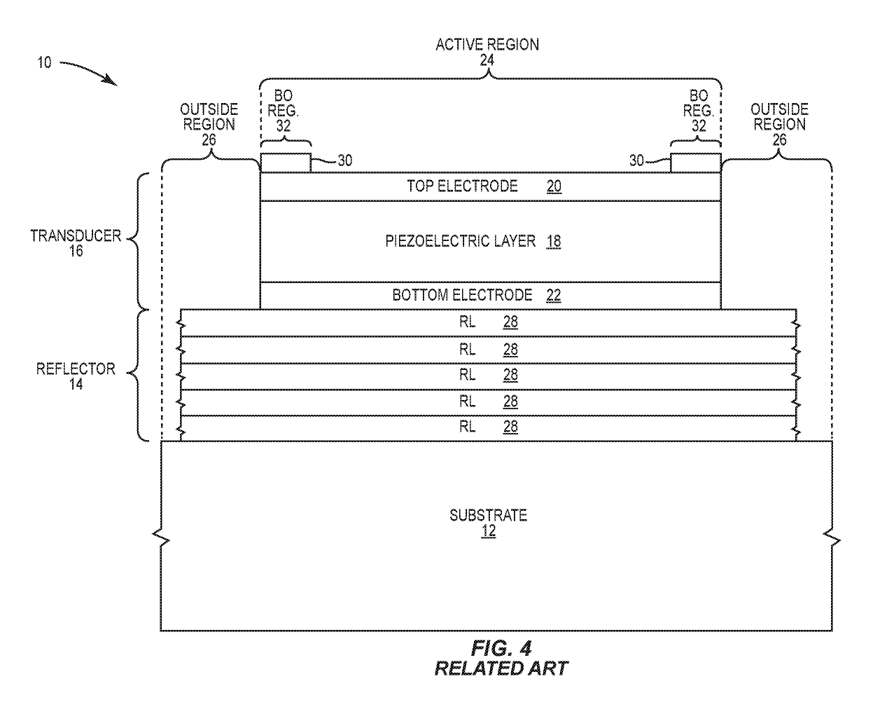

As illustrated in FIG. 4, a border (BO) ring 30 is formed on or within the top electrode 20 to suppress certain of the spurious modes. The spurious modes that are suppressed by the BO ring 30 are those above the series resonance frequency (fₛ), as highlighted by circles A and B in the phase curve of FIG. 3B. Circle A shows a suppression of the ripple, and thus the spurious mode, in the passband of the phase curve, which resides between the series resonance frequency (fₛ) and the parallel resonance frequency (fₚ). Circle B shows suppression of the ripple, and thus the spurious modes, above the parallel resonance frequency (fₚ). Notably, the spurious mode in the upper shoulder of the passband, which is just below the parallel resonance frequency (fₚ), and the spurious modes above the passband are suppressed, as evidenced by the smooth or substantially ripple-free phase curve between the series resonance frequency (fₛ) and the parallel resonance frequency (fₚ) and above the parallel resonance frequency (fₚ).

The BO ring 30 corresponds to a mass loading of the portion of the top electrode 20 that extends about the periphery of the active region 24. The BO ring 30 may correspond to a thickened portion of the top electrode 20 or the application of additional layers of an appropriate material over the top electrode 20. The portion of the BAW resonator 10 that includes and resides below the BO ring 30 is referred to as a BO region 32. Accordingly, the BO region 32 corresponds to an outer, perimeter portion of the active region 24 and resides inside of the active region 24.

While the BO ring 30 is effective at suppressing spurious modes above the series resonance frequency (fₛ), the BO ring 30 has little or no impact on those spurious modes below the series resonance frequency (fₛ), as shown by the ripples in the phase curve below the series resonance frequency (fₛ) in FIG. 3B. A technique referred to as apodization is often used to suppress the spurious modes that fall below the series resonance frequency (fₛ).

Apodization tries to avoid, or at least significantly reduce, any lateral symmetry in the BAW resonator 10, or at least in the transducer 16 thereof. The lateral symmetry corresponds to the footprint of the transducer 16, and avoiding the lateral symmetry corresponds to avoiding symmetry associated with the sides of the footprint. For example, one may choose a footprint that corresponds to a pentagon instead of a square or rectangle. Avoiding symmetry helps reduce the presence of lateral standing waves in the transducer 16. Circle C of FIG. 3C illustrates the effect of apodization in which the spurious modes below the series resonance frequency (fₛ) are suppressed, as evidence by the smooth or substantially ripple-free phase curve below the series resonance frequency (fₛ). Assuming no BO ring 30 is provided, one can readily see in FIG. 3C that apodization fails to suppress those spurious modes above the series resonant frequency (fₛ). As such, the typical BAW resonator 10 employs both apodization and the BO ring 30.

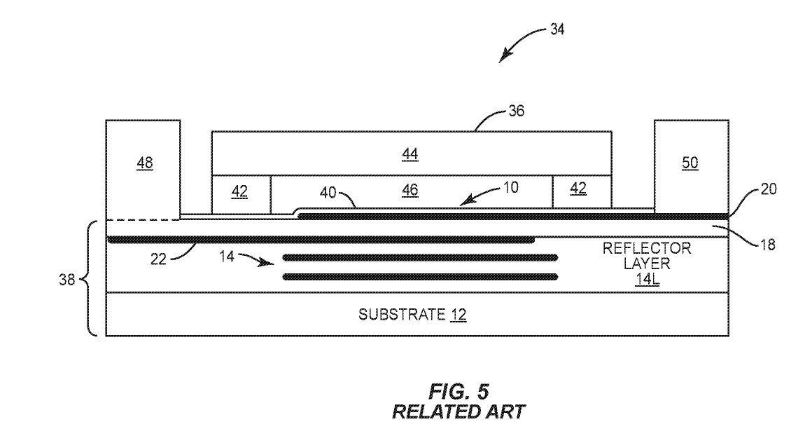

With reference to FIG. 5, a WLP device 34 is illustrated with a conventional cap structure 36. The cap structure 36 sits on, what is referred to as a WLP core 38. The WLP core 38 is essentially the wafer substrate and any device layers in and/or on which components are formed. In this example, the WLP core 38 includes a substrate 12 and all of the device layers above the substrate 12 that are used to form the BAW resonator 10. In particular, the device layers may include a reflector layer 14L in which the reflector 14 is formed, the bottom electrode 22, the piezoelectric layer 18, the top electrode 20, and a passivation layer 40. The passivation layer 40 functions to protect the underlying layers and is typically configured as a dielectric. In this example, the passivation layer 40 is the top layer of the WLP core 38.

The cap structure 36 includes a perimeter wall 42 and a lid 44. The perimeter wall 42 rests on the top of the WLP core 38, and in this example, the passivation layer 40. The lid 44 rests on a top surface of the perimeter wall 42 and forms a cavity 46 that is defined by the top surface of the WLP core 38, the inside surfaces of the perimeter wall 42, and the exposed portion of the bottom surface of the lid 44. In this example, the active region of the BAW resonator 10 is covered by the cavity 46, such that no portion of the perimeter wall 42 rests directly on or above the active region of the BAW resonator 10.

Notably, the lid 44 is formed such that the sidewalls of the lid 44 extend out to and are aligned with the sidewalls of the perimeter wall 42. As such, the lid 44 essentially covers the entire top surface of the perimeter wall 42. Further, the cap structure 36 may reside between one or more interconnect structures, such as a first interconnect structure 48 and a second interconnect structure 50. The first and second interconnect structures 48, 50 may represent copper pillars, which are capped with some form of solder to facilitate physical and electrical attachment to another printed circuit board, module, or the like. In this example, the first interconnect structure 48 is electrically coupled to the bottom electrode 22 of the BAW resonator 10, and the second interconnect structure 50 is electrically coupled to the top electrode 20 of the BAW resonator 10.

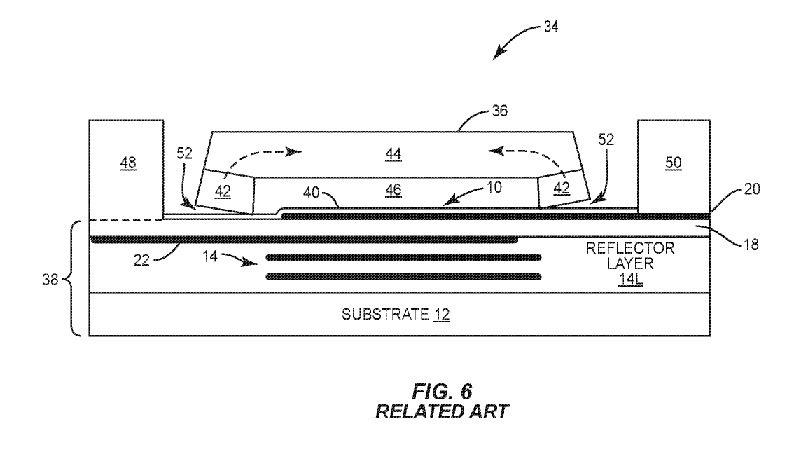

Unfortunately, the cap structure 36 is prone to delaminate from the WLP core 38. The perimeter wall 42 and the lid 44 are often formed from photo-definable dry film epoxies, which tend to shrink as they are cured during typical wafer processing. Once the lid 44 is attached to the top surface of the perimeter wall 42 and temperatures rise during subsequent processing steps, the lid 44 is prone to shrink along the lateral plane, as illustrated in FIG. 6. Since the outer ends of the lid 44 are attached to the top surface of the perimeter wall 42, lateral shrinkage of the lid 44 results in an inward pulling of the top surface of the perimeter wall 42. As a result, excessive torque is applied inwardly at the top of the perimeter wall 42, causing the perimeter wall 42 to lean inward and the bottom surface of the perimeter wall 42 to delaminate from the top surface of the WLP core 38. Delamination portions 52 at the base of the perimeter wall 42 are illustrated, wherein outer portions of the perimeter wall 42 are pulled away from the top surface of the WLP core 38, and in this example, the top surface of the passivation layer 40.

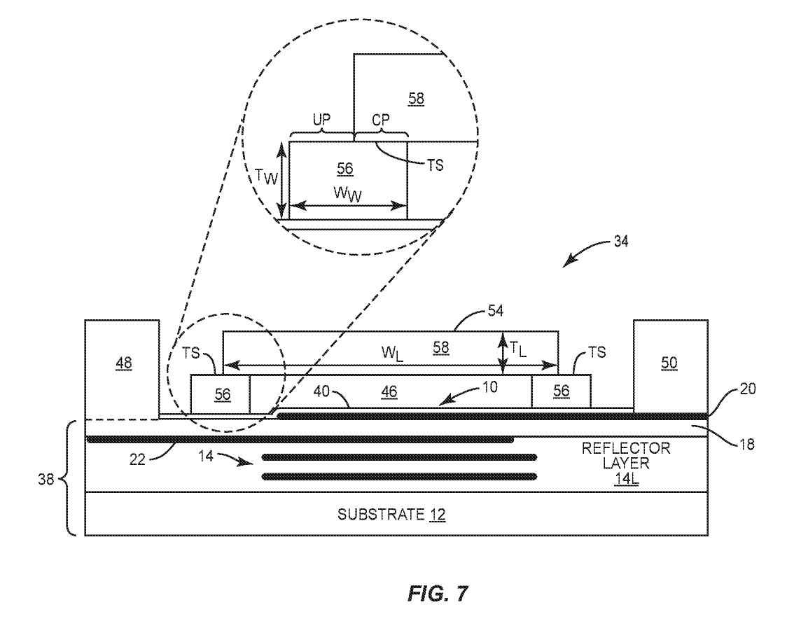

To significantly reduce, if not eliminate, the delamination described above, the present disclosure relates to forming a unique cap structure 54 wherein only a portion of the top surface of a perimeter wall 56 is covered by a lid 58, as illustrated in FIG. 7. For purposes of description, the top surface TS of the perimeter wall 56 is divided into an uncovered portion UP and a covered portion CP. The lid 58 will cover the covered portion CP, but not cover the uncovered portion UP. Applicants have discovered that not fully covering the top surface of the perimeter wall 56 with the lid 58 significantly reduces the torque applied to the perimeter wall 56 if the lid 58 shrinks laterally during and after fabrication. The relative sizes of the uncovered portion UP and the covered portion CP are generally a function of the width WL and thickness TL of the lid 58, and the width WW and thickness TW of the perimeter wall 56.

In one embodiment, the covered portion CP is at least 5 microns (um). The maximum size of the covered portion CP is typically a function of the width WW of the perimeter wall 56. The wider the perimeter wall 56, the better the perimeter wall 56 is anchored to the WLP core 38, and the better the perimeter wall 56 can withstand torque and resist delamination from the WLP core 38. Table 1 below provides exemplary maximum widths (CPmax) of the covered portion CP for various perimeter wall widths WW. This solution is generally valid at least for perimeter wall thicknesses TW of 5 um to 50 um and lid thicknesses TL of 10 um to 100 um. The relationship in Table 1 is represented by the quadratic equation:

CPmax=0.002267*(WW)²+0.5539*WW−1.045.

TABLE 1

| Perimeter Wall Width | Maximum Width of Covered Portion |
|---|---|
| WW (um) | CPmax (um) |
| 10 | 5 |
| 15 | 7.5 |
| 20 | 10 |
| 25 | 14 |
| 30 | 18 |
| 40 | 26 |
| 50 | 33 |
| 60 | 40 |
| 70 | 49 |
| 80 | 56 |
| 90 | 67 |
| 100 | 78 |

In different embodiments, the covered portion CP of the top surface TS of the perimeter wall 56 is no more than 50%, 60%, 70%, or 80% of the width WW of the perimeter wall 56.

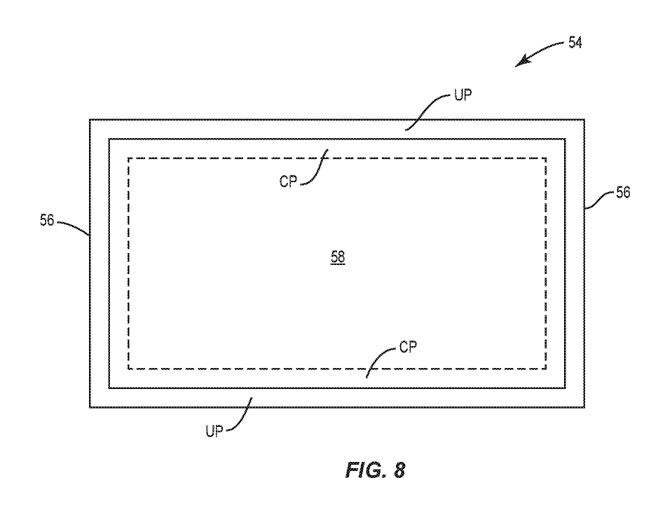

FIG. 8 illustrates a top view of the cap structure 54. This view highlights how the perimeter wall 56 may surround a component formed in or on the WLP core 38. This view also highlights how the lid 58 does not cover the entire top surface of the perimeter wall 56. Instead, an outer periphery of the bottom surface of the lid 58 rests on and only covers the covered portion CP of the top surface TS of the perimeter wall 56, wherein the uncovered portion UP is not covered by the lid 58. As such, the lid 58 does not extend to the outer sidewall of the perimeter wall 56.

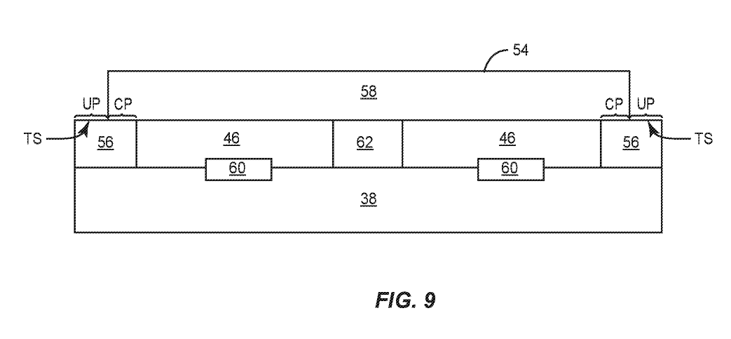

FIG. 9 illustrates an embodiment wherein multiple cavities 46 are formed under a single cap structure 54. The cavities 46 are substantially isolated from one another. The WLP core 38 provides at least one electronic component 60, such as the BAW resonator 10, or cluster of circuitry for each cavity 46. To form the various cavities 46, at least one interior wall 62 is provided between the bottom surface of the lid 58 and a top surface of the WLP core 38. The perimeter wall 56 is formed as described above, wherein only a portion of the top surface of the perimeter wall 56 is covered by the lid 58. The entire top surface of the interior wall 62 is covered by the lid 58. The cavities 46 may have different shapes and sizes with respect to the surface area of the WLP core 38 that is covered by the cavities 46.

The WLP core 38 may be a portion of the wafer formed from any material system, such as gallium arsenide, gallium nitride, silicon, silicon carbide, silicon germanium, and the like. The perimeter wall 56 and the lid 58 may be formed from the same or different materials. In the embodiments described above, the perimeter wall 56 and the lid 58 are formed from photo-definable dry film epoxies, which tend to be 10-80 um thick. Examples of such films include SU8, TMMF, or other permanent photodefinable polyimides

Those skilled in the art will recognize improvements and modifications to the preferred embodiments of the present disclosure. All such improvements and modifications are considered within the scope of the concepts disclosed herein and the claims that follow.

What is claimed is:

1. A wafer level package comprising:
a wafer level core in or on which at least one component is formed; and
a cap structure on a top surface of the wafer level core and forming at least one cavity over the at least one component, the cap structure comprising:
a perimeter wall extending about the at least one component on the top surface of the wafer level core, wherein the perimeter wall has a top surface divided into a covered portion that extends along an inside portion of the top surface of the perimeter wall and an uncovered portion that extends along an outside portion of the top surface of the perimeter wall; and
a lid having a bottom surface, wherein an outer periphery of the bottom surface of the lid rests on and only covers the covered portion of the top surface of the perimeter wall, such that the at least one cavity is defined at least in part by portions of the bottom surface of the lid, an interior sidewall of the perimeter wall, and a top surface of the wafer level core.

2. The wafer level package of claim 1 wherein the perimeter wall completely surrounds the at least one component, and both the covered portion and the uncovered portion of the perimeter wall extends along an entirety of the perimeter wall.

3. The wafer level package of claim 2 wherein the cap structure forms a plurality of cavities, including the at least one cavity, and further comprises at least one interior wall that extends between the bottom surface of the lid and the top surface of the wafer level core, such that the at least one interior wall separates at least two of the plurality of cavities.

4. The wafer level package of claim 2 wherein the covered portion of the top surface of the perimeter wall is no more than a maximum width, and the maximum width is defined as 0.002267*(WW)²+0.5539*WW−1.045, wherein WW is an overall width of the perimeter wall.

5. The wafer level package of claim 4 wherein the overall width of the perimeter wall is 5 μm to 50 μm and a thickness of the lid is 10 μm to 100 μm.

6. The wafer level package of claim 5 wherein the lid and the perimeter wall are formed from an epoxy.

7. The wafer level package of claim 6 wherein the at least one component is a bulk acoustic wave resonator.

8. The wafer level package of claim 5 wherein the cap structure forms a plurality of cavities, including the at least one cavity, and further comprises at least one interior wall that extends between the bottom surface of the lid and the top surface of the wafer level core, such that the at least one interior wall separates at least two of the plurality of cavities.

9. The wafer level package of claim 1 wherein the cap structure forms a plurality of cavities, including the at least one cavity, and further comprises at least one interior wall that extends between the bottom surface of the lid and the top surface of the wafer level core, such that the at least one interior wall separates at least two of the plurality of cavities.

10. The wafer level package of claim 1 wherein the covered portion of the top surface of the perimeter wall is no more than 50% of an overall width of the perimeter wall.

11. The wafer level package of claim 1 wherein the covered portion of the top surface of the perimeter wall is no more than 60% of an overall width of the perimeter wall.

12. The wafer level package of claim 1 wherein the covered portion of the top surface of the perimeter wall is no more than 70% of an overall width of the perimeter wall.

13. The wafer level package of claim 1 wherein the covered portion of the top surface of the perimeter wall is no more than a maximum width, and the maximum width is defined as 0.002267*(WW)²+0.5539*WW−1.045, wherein WW is an overall width of the perimeter wall.

14. The wafer level package of claim 13 wherein the overall width of the perimeter wall is 5 μm to 50 μm and a thickness of the lid is 10 μm to 100 μm.

15. The wafer level package of claim 1 wherein the lid and the perimeter wall are formed from a same material.

16. The wafer level package of claim 1 wherein the lid and the perimeter wall are formed from an epoxy.

17. The wafer level package of claim 1 wherein the lid and the perimeter wall are formed from a photo-definable dry film epoxy.

18. The wafer level package of claim 1 wherein the at least one component is an acoustic resonator.

19. The wafer level package of claim 18 wherein the acoustic resonator is a bulk acoustic wave resonator.

20. A wafer level package comprising:
a wafer level core in or on which a first component and a second component are formed; and
a cap structure on a top surface of the wafer level core and forming a first cavity over the first component and a second cavity over the second component, the cap structure comprising:
a perimeter wall extending completely about the first component and the second component on the top surface of the wafer level core, wherein the perimeter wall has a top surface divided into a covered portion that extends completely along an inside portion of the top surface of the perimeter wall and an uncovered portion that extends completely along an outside portion of the top surface of the perimeter wall; and
a lid having a bottom surface, wherein an outer periphery of the bottom surface of the lid rests on and only covers the covered portion of the top surface of the perimeter wall; and
an interior wall that extends from the bottom surface of the lid to the top surface of the wafer level core, wherein the interior wall separates the first cavity from the second cavity.

21. The wafer level package of claim 20 wherein the covered portion of the top surface of the perimeter wall is no more than a maximum width, and the maximum width is defined as 0.002267*(WW)²+0.5539*WW−1.045, wherein WW is an overall width of the perimeter wall.

22. The wafer level package of claim 21 wherein the overall width of the perimeter wall is 5 μm to 50 μm and a thickness of the lid is 10 μm to 100 μm.
